(19) United States
(12) Patent Application Publication
(10) Pub. No.: US 2023/0317529 A1
(43) Pub. Date: Oct. 5, 2023

(54) METHOD OF TESTING STRUCTURES AND STACKING WAFERS

(71) Applicant: XILINX, INC., San Jose, CA (US)

(72) Inventors: Yan WANG, San Jose, CA (US); I-Ru CHEN, Campbell, CA (US); Nui CHONG, San Jose, CA (US); Hui-Wen LIN, San Jose, CA (US)

(21) Appl. No.: 17/712,052

(22) Filed: Apr. 1, 2022

(51) Int. Cl. H01L 21/66; H01L 21/78; H01L 21/321; H01L 23/00; G01R 31/28

(52) U.S. Cl. CPC H01L 22/14; H01L 21/78; H01L 21/3212; H01L 24/80; H01L 22/32; G01R 31/2884; H01L 2224/80895; H01L 2224/80896

(57) ABSTRACT

Disclosed herein are integrated circuit (IC) structures and methods for fabricating and testing such IC structures prior to dicing from a semiconductor wafer on which the IC structures are formed. In one example, a method for fabricating an IC structure includes contacting a first plurality of test pads of the IC structure with one or more test probes. The first plurality of test pads are disposed within or on a first dielectric layer within a scribe lane, i.e., a test region. A first metal layer is formed over the first plurality of test pads if a predefined test criteria is met as determined using information obtained through first plurality of test pads using the one or more test probes. The first metal layer is a layer formed in a die region of an IC die that is being fabricated in the wafer.

### TECHNICAL FIELD

Examples of the present disclosure generally relate to an apparatus and method of testing structures in a semiconductor wafer prior to dicing of the semiconductor wafer.

### BACKGROUND

Integrated circuit (IC) dies include numerous electrical and/or electronic elements that are fabricated on silicon wafers. A three-dimensional ICs (3DICs) can be fabricated by bonding two or more wafers together. After bonding the wafers, additional processing can be performed, including testing of the 3DICs to identify die defects or characteristics of connections created by the bonding and of components that are formed after bonding together multiple wafers. However, testing after the wafers are bonded risks significant loss of resources and production time should one of the wafers have a low yield, and hence a large number of defective dies. Thus, many fabricators test wafers prior to bonding to screen out one or more known bad die(s). But testing wafers prior to bonding often damages the contact pads utilized to interface test probes. The damaged contact pads often lead to poor wafer to wafer bonding, which itself is a defect. In addition, in many wafer on wafer product partition scenarios, circuits in a single die cannot fully support testing features due to a lack of complete power delivery network, clock network, probe pads, or ESD protection, prior to attaching other dies.

Accordingly, improved integrated circuit structures having test structures, and methods for fabricating and testing the same are needed.

### SUMMARY

Examples described herein relate to integrated circuit structures having testing structures, and methods for fabricating and testing the same. In one example, a method for fabricating a integrated circuit structure includes contacting, prior to completion of die formation on a first wafer, a first plurality of test pads exposed on a first interior metal layer of the first wafer with one or more test probes. The first plurality of test pads is coupled to a plurality of test structures. The first plurality of test pads and the plurality of test structures are formed in a scribe lane of the first wafer. The method proceeds by testing the test structures utilizing one or more signals provided by the one or more test probes to the first plurality of test pads. The method continues by forming, based on the testing the test structures meeting a predefined criteria, at least a second metal layer on the first wafer over the first interior metal layer.

In another example, a method of wafer testing is disclosed. The method includes contacting, prior to completion of die formation on a first wafer, a first plurality of test pads exposed on a first interior metal layer of the first wafer with one or more test probes. The first plurality of test pads is coupled to a plurality of test structures. The first plurality of test pads and the plurality of test structures are formed in a scribe lane of the first wafer. The method continues by testing the test structures utilizing one or more signals provided by the one or more test probes to the first plurality of test pads. A metric for each test structure is generated. Each metric corresponds to defects in each of the respective test structure. The method proceeds by adding each of the metrics to formulate a sum. Further, the method continues by forming, based on the testing the sum being greater than or equal to a threshold value, at least a second metal layer on the first wafer over the first interior metal layer.

In yet another example, a wafer is provided that includes a plurality of integrated circuit (IC) dies separated by a plurality of scribe lanes. The wafer includes a plurality of test structures formed in the scribe lanes. A first plurality of test pads is formed from a first interior metal layer of the wafer. The first plurality of test pads is configured to receive a test probe when testing the test structures. The wafer also includes a top metal layer formed over the first interior metal layer.

### BRIEF DESCRIPTION OF THE DRAWINGS

So that the manner in which the above-recited features of the present disclosure can be understood in detail, a more particular description of the disclosure, briefly summarized above, may be had by reference to examples, some of which are illustrated in the appended drawings. It is to be noted, however, that the appended drawings illustrate only exemplary examples and are therefore not to be considered limiting of the scope of the disclosure, as the disclosure may admit to other equally effective examples. To facilitate understanding, identical reference numerals have been used, where possible, to designate identical elements that are common to the figures. It is contemplated that elements and features of one example may be beneficially incorporated in other examples without further recitation.

FIG. 1 depicts a simplified plan view of a first surface of a wafer having plural integrated circuit (IC) dies and plural test regions.

FIG. 2 is a plan view of an exemplary IC die and a corresponding test region that has a plurality of test pads prior to dicing of the wafer.

FIG. 3 is a sectional view of the test region taken along line A-A, prior to deposition of a top metal layer on the wafer.

FIG. 4 is sectional view of the IC test region showing additional metal layers disposed over the test pads prior to deposition of the top metal layer on the wafer.

FIG. 5 shows an IC die stack after dicing of a second wafer bonded to the first wafer.

FIG. 6 is a flow diagram of an exemplary method of testing the test structures shown in FIGS. 1-5.

FIG. 7 depicts a simplified layout of the test region shown in FIG. 1.

FIG. 8 depicts an even further simplified layout of the test region showing details of a serpentine chain test structure, such as the test structures illustrated in FIG. 3.

To facilitate understanding, identical reference numerals have been used, where possible, to designate identical elements that are common to the figures. It is contemplated that elements of one example may be beneficially incorporated in other examples.

### DETAILED DESCRIPTION

Examples described herein generally relate to integrated circuit (IC) structures and methods for fabricating and testing such IC structures prior to dicing from a semiconductor wafer on which the IC structures are formed. In one example, a method for fabricating an IC structure includes contacting a first plurality of test pads of the IC structure with one or more test probes. The first plurality of test pads are disposed within or on a first dielectric layer within a scribe lane, i.e., a test region. A first metal layer is formed over the first plurality of test pads if a predefined test criteria is met as determined using information obtained through first plurality of test pads using the one or more test probes. The first metal layer is a layer formed in a die region of an IC die that is being fabricated in the wafer.

In another example when contacting the first plurality of test pads, the probes send and receive one or more test signals in parallel to and from the respective first plurality of test pads. A metric is determined from each of the test structures under test via the test probes, and the individual metrics are added to form a sum. The metrics correspond to whether the controller detects defects in the test structures. In some examples, the sum may be utilized to determine if the defect rate is low enough to warrant continuing to fabricate the wafer and/or stack the wafer with a second wafer. For example, if the sum meets or exceeds a threshold value, the method of fabricating the wafer continues, and a second metal layer is deposited over the first metal layer. This method can repeat until the IC die is completely fabricated. Advantageously, the method enables structures of the wafer to be tested before the fabrication of the wafer is completed. The structures, test pads, and routing in the scribe lane of the wafer have similar structures as routing, contact pads, and structures in the IC die. By testing the test structures before the IC dies have been completed, the fabrication process can be halted if a certain number of the plurality of the test structures are identified as defective. In this manner, the method disclosed herein reduces material waste by ceasing the fabrication of wafers where a certain number of test structures, and therefore IC dies, are likely to be defective. Additionally, embodiments that leverage use of the sum of test metrics to determine wafer acceptability can be tested faster and in-situ the cleanroom, thus reducing production time and costs.

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the claimed invention or as a limitation on the scope of the claimed invention. In addition, an illustrated example need not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations. Additionally, reference to a column or row is for ease of description herein and each does not necessarily indicate a particular direction. In different orientations, a column may be referred to as a row, and vice versa.

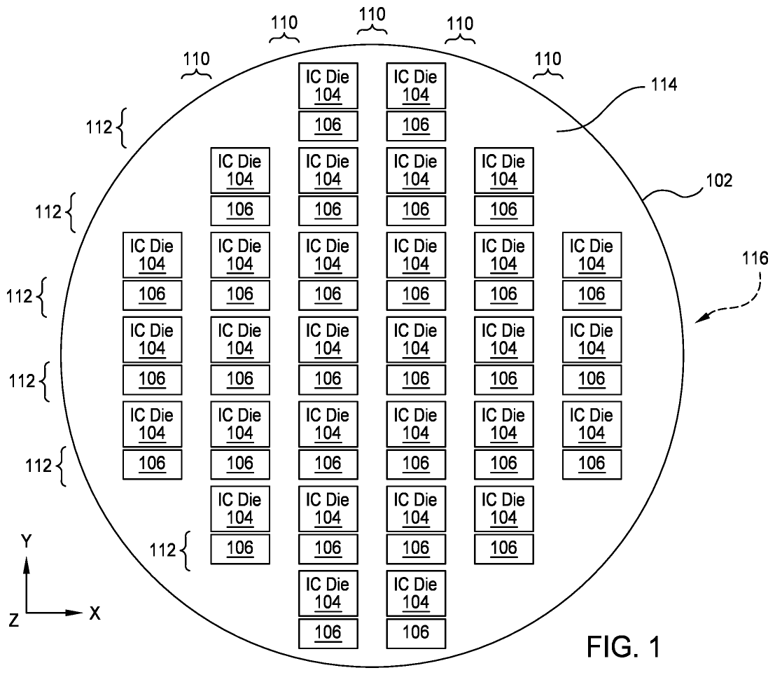

FIG. 1 depicts a simplified layout of a first wafer 102 according to some examples. The first wafer 102, as illustrated, has undergone Front End-of-Line (FEOL) processing along with some of the Back End-of-Line (BEOL) processing. For example, the top metal layer has yet to be deposited on the first wafer 102 depicted in FIG. 1. The first wafer 102 has a plurality of integrated circuit (IC) dies 104 and a plurality of test regions 106. The IC die(s) 104 extend from a top surface 114 towards a bottom surface 116 of the first wafer 102, the bottom surface 116 opposite the top surface 114. Additionally as the top metal layer has yet to be deposited on the first wafer 102, the top surface 114 shown in FIG. 1 will become an interior layer and underlie the top metal layer once deposited when fabrication of the first wafer 102 becomes complete. In the illustrated example, the IC die(s) 104 are arranged in columns and rows on the first wafer 102.

A respective column scribe lane 110 is on the first wafer 102, located between neighboring columns of the IC die(s) 104. Each column scribe lane 110 extends longitudinally in a y-direction, and the column scribe lanes 110 extend longitudinally parallel to each other. A respective row scribe lane 112 is on the first wafer 102 between neighboring rows of the IC die(s) 104. Each row scribe lane 112 extends longitudinally in an x-direction, and the row scribe lanes 112 extend longitudinally parallel to each other. Each y-direction that a column scribe lane 110 longitudinally extends intersects with each x-direction that a row scribe lane 112 longitudinally extends (e.g., although the respective scribe lanes may not intersect). As a person having ordinary skill in the art will readily understand, the column scribe lanes 110 and row scribe lanes 112 are regions where dicing is to be performed to separate stacks of IC dies 104 from the first wafer 102 after bonding with a second wafer.

The first wafer 102 can be wafer bonded to one or more other wafers. Each first wafer 102 includes test regions 106 disposed in one or more of the scribe lanes 110, 112. The test regions 106 are aligned such that the test regions 106 can optionally be electrically connected together when the wafers 102 are bonded together. The test regions 106 can be probed and tested before the first wafer 102 are bonded together, and additionally before all of the layers have been deposited on the first wafer 102. In the example shown, each test region 106 is disposed in row scribe lanes 112 between two adjacent column scribe lanes 110. While the first wafer 102 is only shown with selected test regions 106 paired with a given IC die 104, it is understood that one or more additional IC dies 104 can have an associated test region 106. Accordingly, the arrangement of test regions 106 can vary from the arrangement shown in FIG. 1.

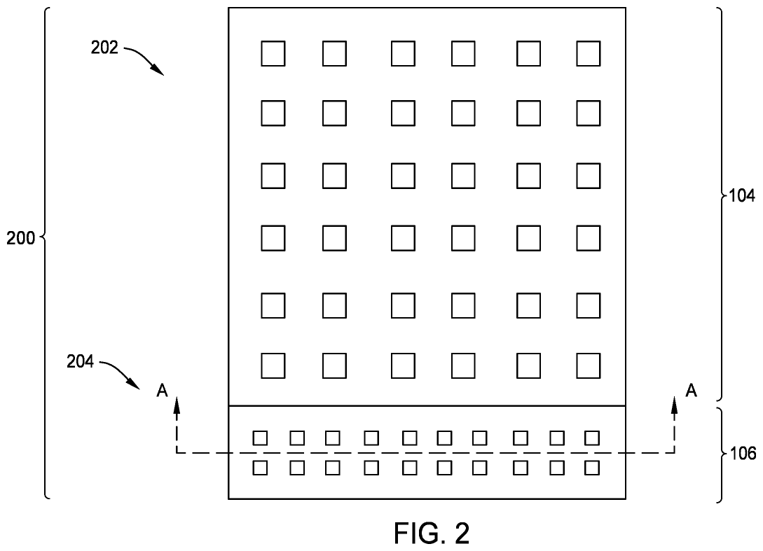

FIG. 2 is a plan view of an exemplary IC die 104 and an adjacent test region 106 showing a plurality of test pads 204. The plurality of test pads 200 are disposed in the test region 106, i.e., scribe lanes 110, 112 shown in FIG. 1. Bond pads 202 are physically and electrically coupled to one or more circuit structures (not shown) of the IC die 104. The bond pads 202 and the plurality of test pads 204 extend up to the top surface 114 of the first wafer 102. The plurality of test pads 204 are made of a conductive material such as copper. The bond pads 202 are also made of a conductive material such as copper. The bond and test pads 202, 204 may be fabricated from the same metal layer during wafer fabrication.

The plurality of test pads 200 are exposed on the top surface 114 of the first wafer 102. While the bond pads 202 and plurality of test pads 200 are shown in a grid-like pattern, it is understood that the arrangement is exemplary, and that other arrangements and configurations are feasible without departing from the scope of the disclosure.

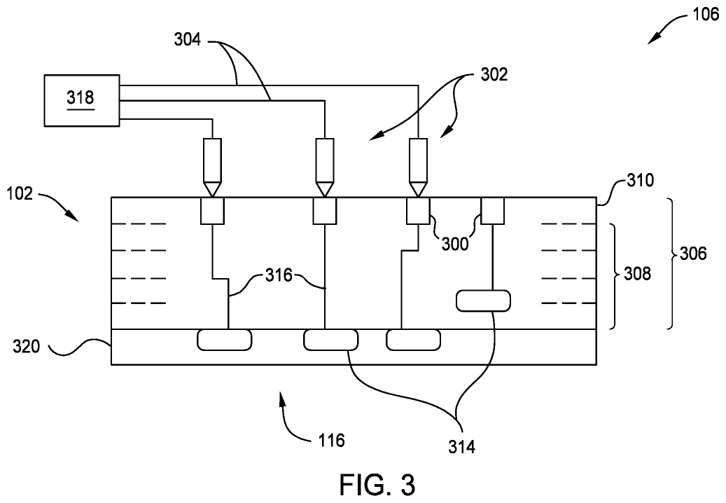

FIG. 3 is a sectional view of the first wafer 102 taken along line A-A, showing a first plurality of test pads 300 contacted by a plurality of probes 302. The first plurality of test pads 300 are disposed in the scribe lanes 110, 112, and correspond to the plurality of test pads 204 shown in FIG. 2. A test controller 318 is coupled to the plurality of probes 302. In at least one example, the controller 318 is coupled to the plurality of probes 302 via signal leads 304. The controller 318 generates and provides one more test signals to the test pads 300 via the plurality of probes 302. In one example, the one more test signals are provided in parallel. In this manner, test structures 314 embedded within a FEOL region 320 or a BEOL region 306 can receive and be tested using the one or more test signals provided by the controller 318 through the test pads 300. Test structures 314 can be formed utilizing critical product design units with full testing peripheral circuit. As such, test structures 314 are formed on scribe lanes 110, 112.

The BEOL region 306 is disposed on top of the FEOL region 320. A silicon substrate upon which the FEOL region 320 is formed is not shown for simplicity. The BEOL region 306 includes a plurality of lower dielectric layers 308 that are interleaved with metal layers (not shown). The metal layers of the BEOL region 306 are patterned to create electrical routings. A first interior metal layer 310 is disposed on the lower dielectric layer 308 farthest from the FEOL region 320. The first interior metal layer 310 is the top surface 114 shown in FIGS. 1 and 2.

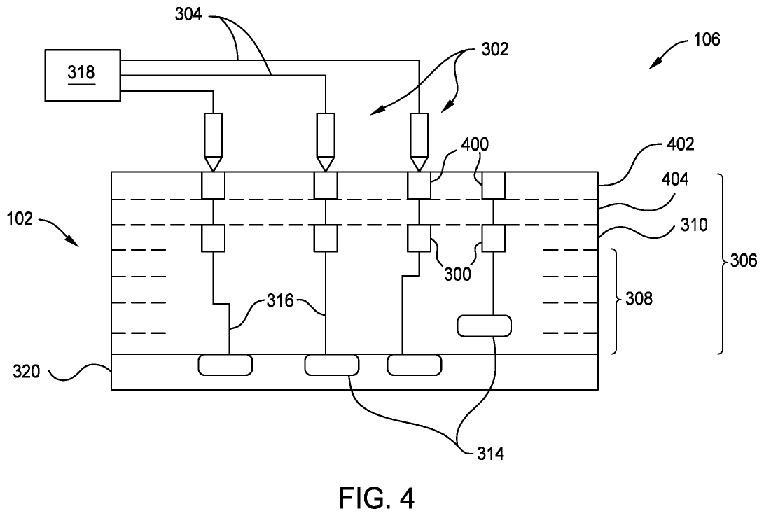

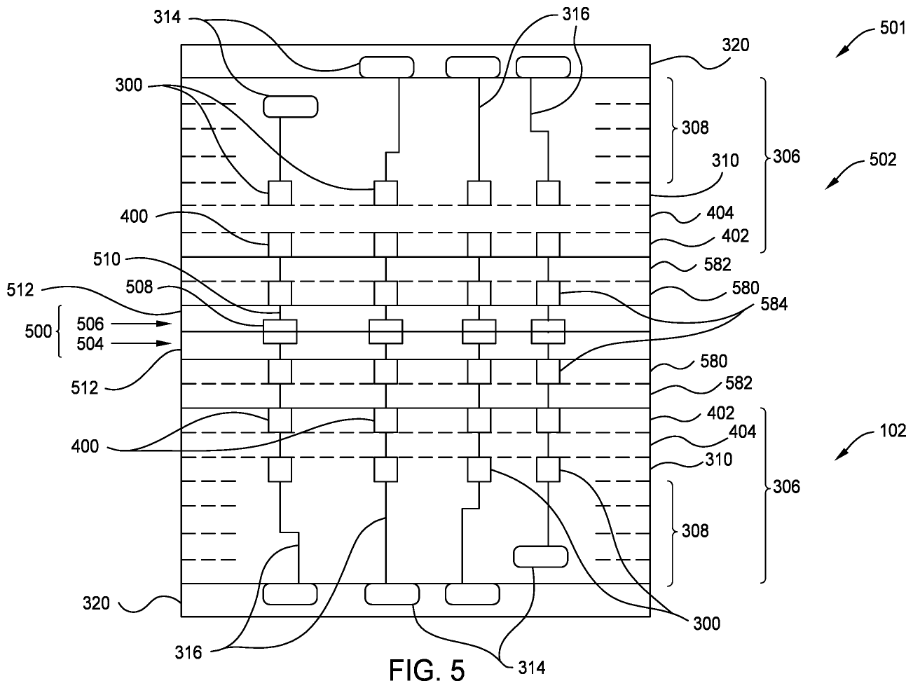

The first plurality of test pads 300 are patterned from the first interior metal layer 310 and are coupled to test structures 314 that are disposed in the BEOL region 306 and/or the FEOL region 320. Prior to disposing an overlying metal layer (which may be another interior metal layer 402 as shown in FIG. 4, or a top metal layer 580, as shown in FIG. 5) over the first interior metal layer 310, the first plurality of test pads 300 is exposed on the BEOL region 306, thereby enabling the first plurality of test pads 300 to be contacted by one or more of the plurality of probes 302 so that the test structures 314 may be tested by the controller 318. By placing test structures 314 beneath test pads 300, surface area of detected metal is increased, thus enabling increased defect sensitivity of the plurality of probes 302 coupled to the controller 318.

The plurality of probes 302 are illustrated in contact with the first plurality of test pads 300. Each one of the plurality of probes 302 is configured to send signals from the controller 318 to the test structures 314. Routing 316, formed from the via and patterned metal layers of the BEOL region 306, carries test signals between the controller 318 and test structures 314. The controller 318 is configured to determine whether the respective test structure 314 has passed or failed a predetermined test criteria based on the test signal provided to the test structures 314.

FIG. 4 is sectional view of the IC die showing one or more additional interior metal layers disposed over the test pads 300 initially shown in FIG. 3. The test pads 300 formed from the metal layer 310 are polished, for example using a chemical mechanical polishing process, to remove damage to the surface of the test pads 300 that may have been caused by the probes 302 prior to depositing additional dielectric and/or metal layers on the first wafer 102. In the example depicted in FIG. 4, a second plurality of test pads 400 are patterned from a second interior metal layer 402. The first plurality of test pads 400 are disposed in the scribe lanes 110, 112, and correspond to the plurality of test pads 204 shown in FIG. 2. The second interior metal layer 402 is disposed on top of the first interior metal layer 310. An intermediate dielectric layer 404 can be disposed between the second interior metal layer 402 and the first interior metal layer 310. The first plurality of test pads 300 have substantially the same configuration as the second plurality of test pads 400, and are connected by vias through the intermediate dielectric layer 404 such that the test pads 400 are coupled to the test structures 314 by the routings 316 as described above. Removing remove any damage to the surface of the test pads 300 prior to deposition of the layers 402, 404 significantly improves the reliability of the electrical connections between the pads 300, 400. The second plurality of test pads 400 are exposed on the BEOL region 306, such that the plurality of probes 302 can contact the second plurality of test pads 400 before the IC dies 104 are completely fabricated, i.e., the top metal layer is deposited.

As illustrated, a respective one of the first plurality of test pads 300 can be electrically coupled to one of the second plurality of test pads 400 by a via through one of the dielectric layers 308. Accordingly, the second plurality of test pads 400 are electrically coupled through the first plurality of test pads 300 to a corresponding test structure 314. The second plurality of test pads 400 can also be coupled to one more test structures 314 disposed in at least one or more layers of the BEOL region 306. Similar to the configuration shown in FIG. 3, routing 316 couples each test structure 314 to a corresponding one of the second plurality of test pads 400. One or more of the plurality of probes 302 contacts second plurality of test pads 400 prior to completion of the IC die 104, which sends and receives signals from the controller 318 to the test structures 314. Routing 316 sends and returns one or more signals to the controller 318, where the controller 318 is configured to determine whether the respective test structure 314 has passed or failed a predetermined test criteria.

FIG. 5 shows a portion of a wafer stack 501 having a second wafer 502 bonded to the first wafer 102. Only a portion of the wafers 501, 502 are shown. A hybrid bond interface layer 500 is disposed between and secures the second wafer 502 and the first wafer 102.

Prior to bonding the wafers 102, 502 together, the top metal layer 580 is formed over the contact pads 400. The top metal layer 580 is patterned to form contact pads 584. The contact pads 584 are coupled to the contact pads 400 by vias formed in a top dielectric layer 582 that separates the top metal layer 580 from the underlying interior metal layer 402. The contact pads 400 formed from the underlying interior metal layer 402 are polished, for example using a chemical mechanical polishing process, to remove damage to the surface of the test pads 400 that may have been caused by the probes 302 prior to depositing the additional dielectric and top metal layers 580, 582 on the wafers 102, 502, thus creating a reliable and robust electrical between the pads 584, 400. Additionally, by testing the test surfaces 314 prior to depositing the top metal layer 580, there is no probe caused surface imperfections on the top metal layer 580, thus enabling a more robust and reliable wafer-to-wafer bond using the hybrid bond interface layer 500.

The hybrid bond interface layer 500 enables IC die(s) 104 and test regions 106 of the first wafer 102 to be electrically connected to the corresponding IC die(s) 104 and test regions 106 of the second wafer 502. While only two wafers (i.e., the first wafer 102 and the second wafer 502) are illustrated, one or more additional wafers (not shown) can be added to the wafer stack 501 utilizing additional hybrid bond interface layers 500, according to implementations disclosed herein.

The hybrid bond interface layer 500 includes a first hybrid bond layer 504 and a second hybrid bond layer 506. Each of the first hybrid bond layer 504 and the second hybrid bond layer 506 has one or more hybrid bond contacts (HBCs) 510 and one or more hybrid bond layers (HBLs) 508. The HBC 510 and the HBL 508 are disposed within one or more layers of a dielectric material 512. Each of the HBC 510 has a first end and a second end, as shown. The HBC 510 is electrically and physically coupled to the HBL 508. The hybrid bond interface layer 500 physically and electrically couples the first wafer 102 to the second wafer 502. For example, the hybrid bond interface layer 500 is electrically and physically coupled to the contact pads 584 formed on the front side of the first wafer 102 to the contact pads 584 formed on the front side of the second wafer 502. In another example (not shown), the hybrid bond interface layer 500 couples the front side of the first wafer 102 to a back side of the second wafer 502, where the front side is opposite the back side of the second wafer 502. After bonding the wafers 102, 502, the stacked wafers are diced along the scribe lanes 110, 112 to separate adjacent die stacks that include at least one die 104 from each wafers 102, 502. Dicing generally removes the test pads and test structures present in the test regions 106.

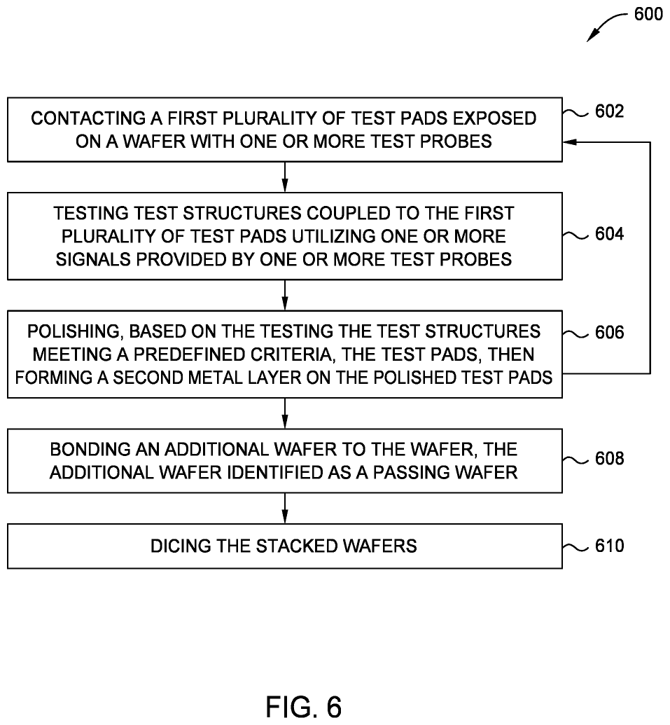

FIG. 6 is a flow diagram of an exemplary method of testing test structures of a wafer. At operation 602, the method 600 begins by contacting a first plurality of test pads exposed on a wafer with one or more test probes. The first plurality of test pads are formed from an interior metal layer of the wafer that will eventually be covered by a top metal layer. For example, prior to completion of IC die 104 formation on the first wafer 102, one or more test probes 302 contact a first plurality of test pads 300 exposed through a surface of the BEOL region 306, as shown in FIG. 3.

At operation 604, the method 600 proceeds by testing the test structures that are coupled to the first plurality of test pads utilizing one or more signals provided to the one or more test probes by a controller. As shown in FIG. 3, one or more probes 302 are coupled to the test controller 318 via the signal leads 304. One or more signals, such as current or voltage-based signal originates from the controller 318 and transmits through the one or more test probes 302 to the test pads 300 from which are routing to the test structures 314. The test structures 314 of a plurality of wafers of a batch can be tested simultaneously, where the batch includes two or more wafers. One or more signals originate from the controller 318, and are provided by the one or more test probes 302 to a plurality of test pads 300 residing over interior metal layers of the plurality of first wafers 102.

Where the test structures do not meet a predefined criteria such a threshold number of test structures that pass testing, the method 600 stops and the first wafer 102 is scrapped. In another example, the predefined criteria is whether the wafer is acceptable or appropriate for continued fabrication of the wafer. Where the test structures meet the predefined criteria, the method 600 continues to operation 606 by polishing the test pads 300 formed from the metal layer 310. The test pads 300 may be polished using a chemical mechanical polishing process, dry etching, or other suitable technique, to remove damage to the surface of the test pads 300 that may have been caused by the probes 302.

After polishing the pads 300, operation 606 additionally includes forming a second metal layer on the wafer. The second metal layer may be the top metal layer or another intermediate/internal metal layer. The second metal layer is patterned to form pads coupled by vias to the pads 300 in the underlying first metal layer. If the second metal layer is the top metal layer or further testing of the test structures will not be performed using pads underlying the top metal layer, the method 600 may proceed to operation 608. If the second metal layer is not the top metal layer and further testing of the test structures will be performed using pads underlying the top metal layer, the method 600 loops back to operation to operation 602 for additional testing.

Testing of the test structures 314 within a first wafer 102 at operation 604 may be conducted in parallel to further reduce testing time. For example, test signals may be provided in parallel to multiple test pads 300 that are contacted with the probes 302. The test signals interfaced with the test structures produce a metric that corresponds to whether a defects is identified in the respective test structure.

At operation 604, that metrics may be added to yield a sum based on past tests. If the sum exceeds a predetermined value, i.e., number of test structures passing the test, the wafer is identified as a passing wafer. For wafer passing at operation 604 and having additional layers deposited over the test pads at operation 606, the method 600 proceeds to operation 608. At operation 608, an additional passing wafer is bonded to the wafer passing the test at operation 604. For example, the first wafer 102 after passing the test at operation 604 is bonded to a second wafer 502 which as also passed the test at operation 604. The second wafer 502 has been formed, tested, and polished according to operations 602 through operation 606. In one example, operation 608 uses a hybrid bond interface layer 500 to electrically and physically couple the first wafer 102 to the second wafer 502, such that the circuitry of the wafers 102, 502 are electrically connected. While the method 600 describes bonding of two wafer 102, 502, it is understood that the additional wafers can be bonded to wafer stack 501 without departing from the scope of this disclosure.

At operation 610, the method 600 proceeds by dicing the stacked IC dies the stacked wafers. For example, after completion of operations 602 to 608, stacked pairs of IC die(s) 104 are diced from the stacked wafers 102, 502, for example, but sawing or ablating the wafers down the scribe lanes 110, 112.

The method 600 may be performed quickly to prevent excessive oxidation of exposed metal surfaces. This both enhances signal transmission both between internal metal layers of the IC die, and between the IC dies across the hybrid bond interface. Additionally, reduces oxidation also makes for a more reliable and robust bond between layers within individual wafers and between the wafers themselves, thereby reducing scrap and production costs. In one example, the time period between testing the test structures of a first batch of wafers and forming the second metal layer is less than 24 hours, such as between about 6 hours and about 12 hours. In some examples, the timer period is less between about 0.5 seconds and about 1 second per test pad. In another example, the time period between completing the testing of the batch and forming the second metal layer on the first wafer and second wafer of the batch is less than about 6 hours, or less than the time it takes for a metal of the test pad to fully oxidize.

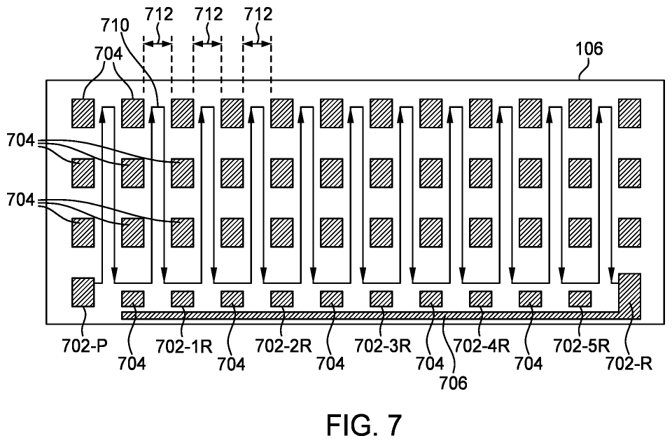

FIG. 7 depicts a simplified layout of the test region 106, according to some examples. The test region 106 includes an array of structure regions. Each structure region of the array can be a chain interconnect region 702, a device under test (DUT) region, and/or a dummy region. For simplicity, a DUT and/or dummy region is indicated in FIG. 7 and referred to herein as DD region 704. In the illustrated example of FIG. 7, the array of structure regions includes four rows (e.g., each row extending along an x-direction) and twelve columns (e.g., each column extending along a y-direction). Other examples contemplate arrays of any size. For example, some examples contemplate eleven rows in an array of structure regions. Additionally, an array may be non-orthogonal, such as a honeycomb array. In other examples, the structure regions can be arranged in any configuration (e.g., not in an array, such as in a stochastic arrangement).

A DD region 704 that is a DUT region includes one or more DUTs (e.g., a process control monitor (PCM)). A DUT can include any of a transistor, a diode, a capacitor, a metal stack (e.g., metal lines and/or vias), and any other appropriate active or passive device or structure. A DUT can be formed fully or partially in a semiconductor substrate of the wafer, in one or more metallization layers (e.g., including metal lines and/or vias) in respective one or more front side dielectric layers on a front side of the semiconductor substrate, and/or in one or more metallization layers in respective one or more backside dielectric layers on a backside of the semiconductor substrate. Further, a single DUT can be formed across multiple wafers, in some examples. A person having ordinary skill in the art will readily understand various DUTs that can be formed and disposed in a DUT region.

A DD region 704, whether a DUT region or a dummy region, can include a number of bond pads and interconnections. The bond pads are formed on the wafer at a surface that will be bonded to another wafer (which will be described in more detail subsequently). The bond pads can be functional pads, such as to carry a signal to or from a DUT, or can be dummy pads, which may not carry a signal and may promote processing uniformity and bonding adhesion. The interconnections can include any combination of metal lines and vias in any metallization layer and through-substrate vias (TSVs) electrically connected together. These interconnections can be functional interconnections, such as electrically connected to functional bond pads and to respective DUTs, or can be dummy interconnections, such as to promote uniformity of processing.

In the illustrated example, each DD region 704 is laterally self-contained (e.g., in x and y-directions) within a lateral boundary of the respective DD region 704. Each DD region 704 does not have a component (e.g., a metal line) that crosses a lateral boundary (e.g., a boundary in an X-Z plane or in a Y-Z plane in the illustrated example) of the DD region 704. Each DD region 704 can be electrically connected (e.g., by bond pads, metal lines, vias, and/or TSVs) to an overlying DD region and/or an underlying DD region of an overlying and/or underlying wafer, respectively, in a bonded wafer stack. Each DD region 704 can be unaffected by a serpentine test structure.

The chain interconnect regions 702 can each be like a DD region 704, as described above, except that the chain interconnect regions 702 include electrical connections to a serpentine chain test structure that is outside of the lateral boundary of the respective chain interconnect region 702. In the illustrated example, the chain interconnect regions 702 are aligned in a same row of the array in the test region 106. The chain interconnect regions 702 include a power chain interconnect region 702-P, a general return chain interconnect region 702-R, a first die return chain interconnect region 702-1R, a second die return chain interconnect region 702-2R, a third die return chain interconnect region 702-3R, a fourth die return chain interconnect region 702-4R, and a fifth die return chain interconnect region 702-5R.

A return interconnect 706 extends from the general return chain interconnect region 702-R and along the die return chain interconnect regions 702-1R, 702-2R, 702-3R, 702-4R, 702-5R. The return interconnect 706 is connected to the general return chain interconnect region 702-R and one of the die return chain interconnect regions 702-1R, 702-2R, 702-3R, 702-4R, 702-5R in the test region 106. The return interconnect 706 is connected to the general return chain interconnect region 702-R and the fifth die return chain interconnect region 702-5R.

A serpentine chain test structure 710 is electrically connected between the power chain interconnect region 702-P and the general return chain interconnect region 702-R. The serpentine chain test structure 710 can include a chain of serially connected TSVs and/or bond pads. Hence, although the serpentine chain test structure 710 may be described in the context of one wafer, a serpentine chain test structure 710 may be formed with components of two or more wafers. Examples are illustrated in a subsequently described figure.

The serpentine chain test structure 710 includes segments disposed in regions 712 of the test region 106 laterally between columns of structure regions and between neighboring structure regions that are in a row of the array in which the chain interconnect regions 702 are not disposed. Each segment of the serpentine chain test structure 710 is disposed between neighboring structure regions that are not the power chain interconnect region 702-P and the general return chain interconnect region 702-R. Each segment of the serpentine chain test structure 710 is disposed laterally between structure regions that are in neighboring columns of the array and that are outside of the row in which the power chain interconnect region 702-P is disposed and the row in which the general return chain interconnect region 702-R is disposed. Each segment of the serpentine chain test structure 710 is disposed in a region 712 between neighboring structure regions that are in different columns in the array and that are in a row of the array different from a row in which the power chain interconnect region 702-P or the general return chain interconnect region 702-R is disposed. For example, the serpentine chain test structure 710 is disposed laterally between neighboring structure regions within a same row of the array and extends substantially parallel to columns of the structure regions of the array. Because the serpentine chain test structure 710 is disposed laterally between neighboring columns of DD regions 704, such DD regions 704 can be unaffected by the serpentine chain test structure 710 and can be unmodified based on the presence of the serpentine chain test structure 710. The serpentine chain test structure 710 can serpentine with any number of switchbacks between neighboring columns.

The serpentine chain test structure 710 crosses columns of the array disposed between the power chain interconnect region 702-P and the general return chain interconnect region 702-R near the die return chain interconnect regions 702-1R, 702-2R, 702-3R, 702-4R, 702-5R and DD regions 704 in a same row as the power chain interconnect region 702-P and the general return chain interconnect region 702-R. Respective sizes of these die return chain interconnect regions 702-1R, 702-2R, 702-3R, 702-4R, 702-5R and DD regions 704 can be reduced (e.g., relative to other DD regions 704 and in a y-direction) to accommodate for area for the serpentine chain test structure 710 to cross the respective column.

In one example, the serpentine chain test structure 710 is disposed in a first tier wafer, such as wafer 102. The serpentine chain test structure 710 is a chain of backside TSVs (not shown) that are electrically connected in series by metal lines and/or vias in the metallizations in one or more front side dielectric layer(s) and in the backside dielectric layer(s) (not shown). The serpentine chain test structure 710 is electrically connected between the metal stack in the power chain interconnect region 702 of the first tier wafer and the metal stack in the first die return chain interconnect region 702-1R of the first tier wafer. A metal feature (e.g., a metal line) in the metallizations in the front side dielectric layer(s) electrically connects the serpentine chain test structure 710-1 to the metal stack in the power chain interconnect region 702-P. Similarly, a metal feature (e.g., a metal line) in the metallizations in the front side dielectric layer(s) electrically connects the serpentine chain test structure 710-1 to a metal line and/or metal stack in the general return chain interconnect region 702-R of the first tier wafer, which metal line and/or metal stack is then electrically connected by the return interconnect 706 (e.g., a metal line in the metallizations in the front side dielectric layer(s)) to the metal stack in the first die return chain interconnect region 702-1R.

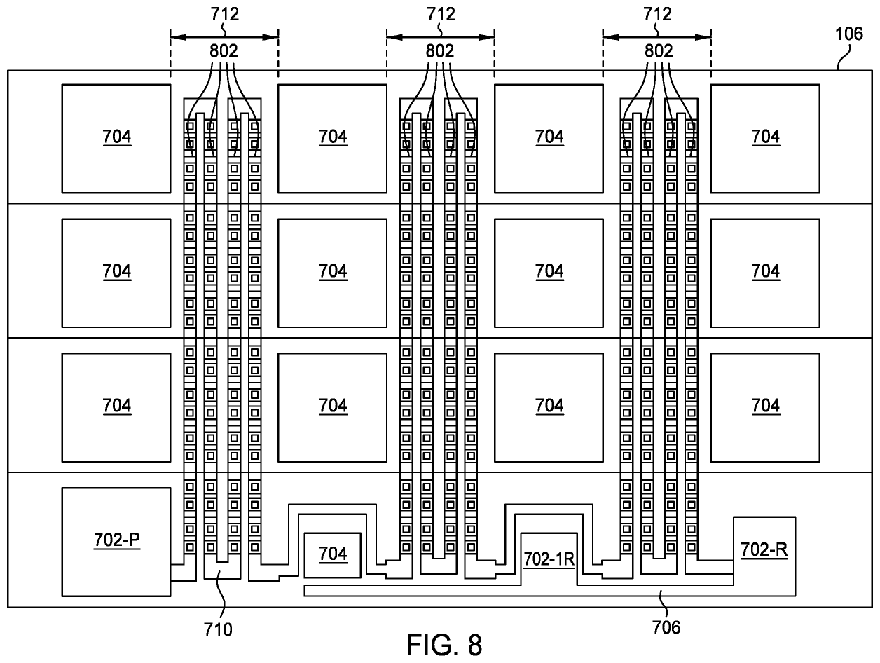

FIG. 8 depicts an even further simplified layout of the test region 106 with additional details of a serpentine chain test structure 710, according to some examples. The test structure 710 is one example of the test structures 314 shown in FIG. 3. The array in FIG. 8 is simplified and smaller for illustrative purposes. FIG. 8 illustrates how the serpentine chain test structure 710 can switchback a number of times in a region 712. In FIG. 8, the serpentine chain test structure 710 has four segments 402 that extend across the four rows of the array in each region 712. Any number of segments spanning any number of the rows of the array can be implemented.

At a current technology node, in some examples, a structure region can have a lateral boundary that is, e.g., approximately 55 μm (in an x-direction)×55 μm (in a y-direction). A width of a row (in a y-direction) of the array a can be approximately 60 μm, which permits approximately 10 μm of separation in a y-direction between neighboring structure regions within a column. A spacing of the region 712 between columns can be approximately 50 μm (in an x-direction). With a 1.4 μm pitch for neighboring TSVs and for neighboring bond pads, examples at this technology node can achieve over 100,000 instances of TSVs and/or bond pads for a serpentine chain test structure implemented across four rows of an array of structure regions of a test region 106, like illustrated in FIG. 7. Such a serpentine chain test structure can have a resistance between 50 kΩ and 100 kΩ, for example. Further, with a 1.4 μm pitch for neighboring TSVs and for neighboring bond pads, examples at this technology node can achieve over 330,000 instances of TSVs and/or bond pads for a serpentine chain test structure implemented across eleven rows of an array of structure regions of a test region 106. Such a serpentine chain test structure can have a resistance between 160 kΩ and 300 kΩ, for example. It is contemplated that changes and/or advances in the technology node at which various examples are implemented can achieve different numbers of instances of components within a serpentine chain test structure and/or different resistances. Further, the serpentine chain test structure can be modularized and can be expanded depending on the area of the scribe line.

A serpentine chain test structure 710-1 is disposed in the first tier wafer 501. The serpentine chain test structure 710-1 is a chain of backside TSVs 561 that are electrically connected in series by metal lines and/or vias in the metallizations in the front side dielectric layer(s) 521 and in the backside dielectric layer(s) 531. The serpentine chain test structure 710-1 is electrically connected between the metal stack in the power chain interconnect region 702-P of the first tier wafer 501 and the metal stack in the first die return chain interconnect region 702-1R of the first tier wafer 501. A metal feature (e.g., a metal line) in the metallizations in the front side dielectric layer(s) 521 electrically connects the serpentine chain test structure 710-1 to the metal stack in the power chain interconnect region 702-P. Similarly, a metal feature (e.g., a metal line) in the metallizations in the front side dielectric layer(s) 521 electrically connects the serpentine chain test structure 710-1 to a metal line and/or metal stack in the general return chain interconnect region 702-R of the first tier wafer 501, which metal line and/or metal stack is then electrically connected by the return interconnect 706 (e.g., a metal line in the metallizations in the front side dielectric layer(s) 521) to the metal stack in the first die return chain interconnect region 702-1R.

Disclosed herein are methods of testing structures in a semiconductor wafer before stacked wafers are diced. Advantageously, the method enables structures to be tested before the individual IC dies disposed on the wafer are completely formed. By testing the structures before the IC dies have been completed, the fabrication process can be halted if a certain plurality of structures are identified as defective. While the foregoing is directed to specific examples, other and further examples may be devised without departing from the basic scope thereof, and the scope thereof is determined by the claims that follow.

What we claim is:

1. A method of wafer testing, comprising:
contacting, prior to completion of die formation on a first wafer, a first plurality of test pads exposed on a first interior metal layer of the first wafer with one or more test probes, the first plurality of test pads coupled to a plurality of test structures, the first plurality of test pads and the plurality of test structures formed in a scribe lane of the first wafer;
testing the test structures utilizing one or more signals provided by the one or more test probes to the first plurality of test pads; and
forming, based on the testing the test structures meeting a predefined criteria, at least a second metal layer on the first wafer over the first interior metal layer.

2. The method of claim 1, wherein forming the second metal layer further comprises:
forming a top metal layer on the first wafer.

3. The method of claim 1 further comprising:
polishing the first plurality of test pads exposed on the first interior metal layer of the first wafer prior to forming the second metal layer on the first wafer over the first interior metal layer.

4. The method of claim 1 further comprising:
contacting, prior to completion of die formation on the first wafer, a second plurality of test pads exposed on a second interior metal layer of the first wafer with one or more test probes, the second plurality of test pads coupled to the plurality of test structures, the second plurality of test pads formed in the scribe lane of the first wafer;
testing the test structures utilizing one or more signals provided by the one or more test probes to the second plurality of test pads; and
forming, based on the testing the test structures meeting a predefined criteria, at least a third metal layer on the first wafer over the second metal layer.

5. The method of claim 1, wherein testing the test structures further comprises:
generating a metric for each test structures, each metrics corresponding to a test pass or test fail of each respective test structure;
adding each of the metrics to formulate a sum; and
forming, based on the sum identifying a passing wafer, at least the second metal layer on the first wafer over the first interior metal layer.

6. The method of claim 1, wherein testing the test structures further comprises:
testing to or more test structures in parallel.

7. The method of claim 1, wherein a time period between testing the test structures and forming the second metal layer is less than about 1 second per test pad.

8. The method of claim 1 further comprising:
testing a test structures of a plurality of wafers of a batch utilizing one or more signals provided by the one or more test probes to a plurality of test pads residing on interior metal layers of the plurality of wafers; and
forming on each of the plurality of wafers meeting the predefined criteria, at least a second metal layer over the first interior metal layer, the first wafer part of the batch.

9. The method of claim 8, wherein a time period between completing the testing the batch and forming the second metal layer on the first and second wafers of the batch is less than about 6 hours.

10. The method of claim 1 further comprising:
bonding the first wafer to a second wafer to form at least part of a wafer stack; and
dicing stacked dies from the wafer stack.

11. The method of claim 10, wherein bonding further comprises:
forming a plurality of hybrid bonds between contact pads exposed on facing surfaces of the first and second wafers.

12. The method of claim 1, wherein dicing further comprises:
separating the test structures from the first and second wafers.

13. A method of wafer testing, comprising:
contacting, prior to completion of die formation on a first wafer, a first plurality of test pads exposed on a first interior metal layer of the first wafer with one or more test probes, the first plurality of test pads coupled to a plurality of test structures, the first plurality of test pads and the plurality of test structures formed in a scribe lane of the first wafer;
testing the test structures utilizing one or more signals provided by the one or more test probes to the first plurality of test pads;
generating a metric for each test structure, each metric corresponding to defects in each of the respective test structures;
adding each of the metrics to formulate a sum; and
forming, based on the testing the sum being greater than or equal to a threshold value, at least a second metal layer on the first wafer over the first interior metal layer.

14. The method of claim 13, wherein forming the second metal layer further comprises:
forming a top metal layer on the first wafer.

15. The method of claim 13 further comprising:
polishing the first plurality of test pads exposed on the first interior metal layer of the first wafer prior to forming the second metal layer on the first wafer over the first interior metal layer.

16. The method of claim 13 further comprising:
contacting, prior to completion of die formation on the first wafer, a second plurality of test pads exposed on a second interior metal layer of the first wafer with one or more test probes, the second plurality of test pads coupled to the plurality of test structures, the second plurality of test pads formed in the scribe lane of the first wafer;
testing the test structures utilizing one or more signals provided by the one or more test probes to the second plurality of test pads; and
forming, based on the testing the test structures meeting a predefined criteria, at least a third metal layer on the first wafer over the second metal layer.

17. The method of claim 13, wherein testing the test structures further comprises:
forming, based on the sum identifying a passing wafer, at least the second metal layer on the first wafer over the first interior metal layer.

18. A wafer comprising:
a plurality of integrated circuit (IC) dies separated by a plurality of scribe lanes;
a plurality of test structures formed in the scribe lanes;
a first plurality of test pads formed from a first interior metal layer of the wafer, the first plurality of test pads configured to receive a test probe when testing the test structures; and
a top metal layer formed over the first interior metal layer.

19. The wafer of claim 18, wherein the test region further comprises:
an array of structure regions, each structure region of the array is one of a chain interconnect region, a device under test (DUT) region, and/or a dummy region, and wherein the first plurality of test pads are formed in one of the scribe lanes.

20. The wafer of claim 18, wherein the test structures are arranged in a serpentine chain of test structures that are electrically connected between a power chain interconnect region and a general return chain interconnect region.
